(19) United States
(12) Patent Application Publication
(10) Pub. No.: US 2009/0284669 A1
(43) Pub. Date: Nov. 19, 2009

(54) Data storing device and storing method for the same

(75) Inventors: An-Cheng Sun, Taipei (TW); Jen-Hwa Hsu, Taipei (TW); Ching-Ray Chang, Taipei (TW)

Correspondence Address: Haverstock & Owens L.L.P., 162 North Wolfe Road, Sunnyvale, CA, 94086, US

(73) Assignee: Ching-Ray Chang

(21) Appl. No.: 12/229,778

(22) Filed: Aug. 26, 2008

(30) Foreign Application Priority Data
May 14, 2008 (TW) 097117737

(51) Int. Cl. G11C 11/00; G11C 11/02

(52) U.S. Cl. 349/1; 365/129

(57) ABSTRACT

A memory cell is provided in the present invention. The memory cell includes a first electrode receiving a first voltage to form an electric field therearound; and a combination arranged on the first electrode, comprising a liquid crystal molecule coupled with a magnetic substance for forming a magnetic field therearound, wherein the magnetic field changing with the first electric field.

### FIELD OF THE INVENTION

The present invention relates to a data storing device, in particular, to a digital data storing device.

### BACKGROUND OF THE INVENTION

Liquid crystals are substances that exhibit a phase of matter that has properties between those of a conventional liquid, and those of a solid crystal. For instance, a liquid crystal (LC) may flow like a liquid, but have the molecules in the liquid arranged and/or oriented in a crystal-like way.

The out appearance of a LC molecule is an ellipse-like strip. Usually, LC molecules are regularly ordered or orientationally arranged with each other in the way such that the longitudinal axes of LC molecules are almost parallel to each other. Such orientational arrangement is regarded as the alignment in the relevant technical field. There are many different types of LC molecule, which can be distinguished by the type of ordering or arrangement that is present. Typically one can distinguish orientational order by determining whether LC molecules are arranged in any sort of ordered lattice or whether molecules are mostly pointing in the same direction. Therefore, LC molecules can be accordingly categorized into three ordinary types such as nematic, smectic and cholesteric LC molecule.

Please refer to FIG. 1(a), which is a schematic diagram illustrating an orientational arrangement of LC molecules without being influenced by an external applied electrical field according to the present application. In the meanwhile, please also refer to FIG. 1(b), which is a schematic diagram illustrating an orientational alignment of LC molecules being influenced by an external applied electrical field according to the present application. In FIGS. 1(a) and 1(b), an upper substrate 10a, a lower substrate 10b, an upper electrode 12a, a lower electrode 12b and a long-chain LC molecules 14 are shown therein. Please first referring to FIG. 1(a), an external applied electrical field is not applied to the long-chain LC molecules 14 so that the long-chain LC molecules 14 is not influenced by the external applied electrical field. The long-chain LC molecules 14 are horizontally rested between the upper substrate 10a and the lower substrate 10b and twisted with 90 degrees from the lower substrate 10b to the upper substrate 10a. That is, the longitudinal axes of the long-chain LC molecules 14 are approximately parallel to the upper substrate 10a and the lower substrate 10b. Please keep referring to FIG. 1(b). A voltage difference is applied between the upper electrode 12a and the lower electrode 12b for forming an external applied electrical field between the upper substrate 10a and the lower substrate 10b. The long-chain LC molecules 14 is now influenced by such external applied electrical field so that the orientational alignment of the long-chain LC molecule 14 is transited from a horizontal orientational alignment to a vertical orientational alignment. That is, longitudinal axes of the long-chain LC molecules 14 are approximately perpendicular to the upper substrate 10a and the lower substrate 10b.

Conventionally, the LC molecules having the above-mentioned technical features are widely applied to various flat panel displays. However, it has rarely seen any technological renovation in other technical field except for the display field that utilizes the above-mentioned technical features possessing by the LC molecules.

To overcome the mentioned drawbacks of the prior art, a surface treatment method and device thereof are provided.

### SUMMARY OF THE INVENTION

According to the first aspect of the present invention, a memory cell is provided. The memory cell includes a first electrode receiving a first voltage to form an electric field therearound; and a combination arranged on the first electrode, comprising a liquid crystal molecule coupled with a magnetic substance for forming a magnetic field therearound, wherein the magnetic field changing with the first electric field.

Preferably, the memory cell further includes a second electrode wherein the combination is arranged between the first electrode and the second electrode and a voltage difference is applied between the first electrode and the second electrode to form an electric field.

Preferably, the memory cell further includes a first substrate and a second substrate, on which the first electrode and the second electrode are respectively disposed.

Preferably, the substrate is one of a glass substrate and a semiconductor substrate.

Preferably, the memory cell further includes a substrate on which the first electrode is disposed.

Preferably, the memory cell further includes a substrate having a first side, on which the first electrode is disposed, and a second side; and a second electrode disposed on the second side, wherein the combination is arranged between the first electrode and the second electrode and the second electrode receives a second voltage to form a second electric field therearound.

Preferably, the memory cell further includes a switch for controlling the voltage.

Preferably, the switch is a transistor.

Preferably, the liquid crystal molecule is one selected from a group consisting of a nematic liquid crystal molecule, a smectic liquid crystal molecule, a cholesteric liquid crystal molecule, a discotic liquid crystal molecule, a thermotropic liquid crystal molecule and a recentrant liquid crystal molecule.

Preferably, the magnetic substance has a shape selected from a group consisting of an elongated shape, a pin shape and a stripe shape.

Preferably, the magnetic substance has a longitudinal axis parallel to a longitudinal axis of the liquid crystal molecule.

Preferably, the substance has a nanoscaled size.

Preferably, the liquid crystal molecule and the magnetic substance are coupled with each other by one of an electrostatic force and a van der Waals force for forming the combination.

According to the second aspect of the present invention, a memory cell is provided. The memory cell includes an electrode; a combination arranged on the electrode, comprising a liquid crystal molecule and a magnetic substance, wherein the arrangement of the combination changes with the an electric field formed by a voltage applied to the electrode.

According to the third aspect of the present invention, a memory device has a plurality of memory cells is provided.

According to the fourth aspect of the present invention, a memory device is provided. The memory device includes a plurality of memory cells, each of which comprises an electrode; and a plurality of combinations arranged on the electrode, each of which comprises a liquid crystal molecule and a magnetic substance; and a magnetic sensor, wherein a voltage is applied to the electrode to vary an arrangement of the combination so that a variation of a magnetic field formed around the cell is sensed by the magnetic sensor.

Preferably, the memory device further includes a second electrode, wherein the combinations are arranged between the first electrode and the second electrode, and a voltage is applied between the first electrode and the second electrode to form an electric field.

Preferably, the memory device further includes a substrate having a first side, on which the first electrode is disposed, and a second side; and a second electrode disposed on the second side, where the combinations are arranged between the first electrode and the second electrode, wherein a first voltage is applied to the first electrode to form a first electric field therearound, and a second voltage is applied to the second electrode to form a second electric field therearound.

According to the fifth aspect of the present invention, a data memorizing method is provided. The data memorizing method comprising steps of applying a voltage to an electrode on which a combination comprising a liquid crystal molecule and a magnetic substance; and varying the voltage to vary a magnetic field formed around the combination.

According to the sixth aspect of the present invention, a device for implementing the data memorizing method is provided.

The foregoing and other features and advantages of the present invention will be more clearly understood through the following descriptions with reference to the drawings:

### BRIEF DESCRIPTION OF THE DRAWINGS

FIG. 1(a) is a schematic diagram illustrating an orientational arrangement of LC molecules without being influenced by an external applied electrical field according to the present application;

FIG. 1(b) is a schematic diagram illustrating an orientational alignment of LC molecules being influenced by an external applied electrical field according to the present application;

FIG. 2(a) is a schematic diagram illustrating an orientational arrangement of the combinations in the memory cell without being influenced by an external applied electrical field according to the present application;

FIG. 2(b) is a schematic diagram illustrating an orientational arrangement of the combinations in the memory cell being influenced by an external applied electrical field according to the present application;

FIG. 3 is a schematic diagram illustrating a first alternative embodied architecture for the memory cell according to the present application;

FIG. 4 is a schematic diagram illustrating a second alternative embodied architecture for the memory cell according to the present application; and

FIG. 5 is a schematic diagram illustrating a digital data memory device according to the present application.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the aspect of illustration and description only; it is not intended to be exhaustive or to be limited to the precise from disclosed.

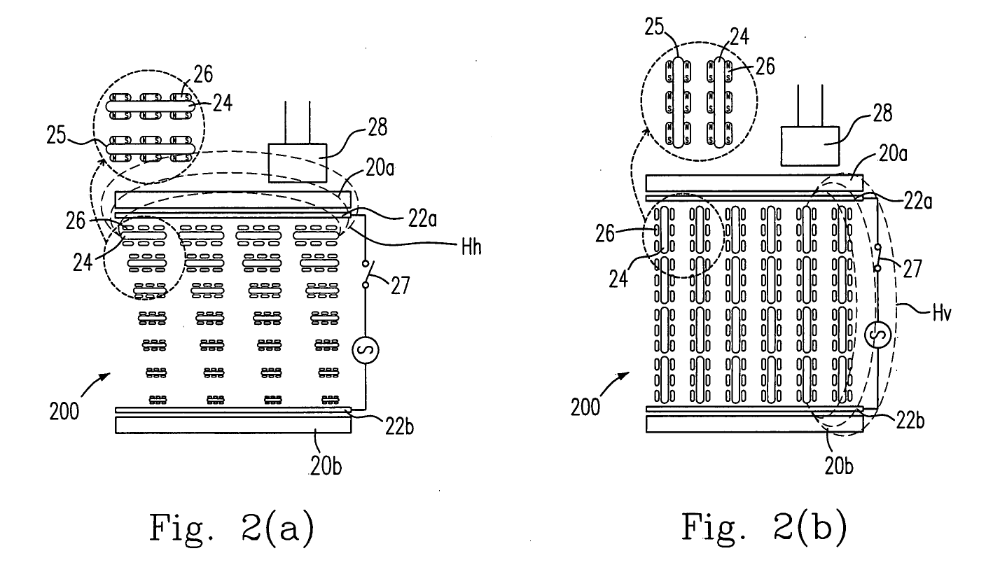

Please refer to FIG. 2(a), which is a schematic diagram illustrating an orientational arrangement of the combinations in the memory cell without being influenced by an external applied electrical field according to the present application. At the same time, please refer to FIG. 2(b), which is a schematic diagram illustrating an orientational arrangement of the combinations in the memory cell being influenced by an external applied electrical field according to the present application. The memory cell 200 in FIGS. 2(a) and 2(b) includes a first substrate 20a, a second substrate 20b, a first electrode 22a, a second electrode 22b, a LC (Liquid Crystal) molecule 24, a magnetic substance 26, a combination 25, a switch 27, a horizontal magnetic field Hh, a vertical magnetic field Hv and a magnetic sensor 28. The LC molecule 24 is a nematic LC molecule, a smectic LC molecule, a cholesteric LC molecule or a long-chain LC molecule. The switch 27 is made as a transistor. The first substrate 20a and the second substrate 20b are a glass-made substrate or a semiconductor-made substrate. The magnetic substance 26 has an elongated form, a pin-shaped form or a stripe-shaped form. The magnetic substance 26 is polarized in advance to become a polar substance or a magnetic substance with polarity.

At least one LC molecule 24 and at least one magnetic substance 26 are coupled with each other by an electrostatic force or a van der Waals force, whereby the combination is formed. In FIGS. 2(a) and 2(b), though each LC molecule 24 is coupled with six magnetic substances 26 having a stripe-shaped form, for a LC molecule 24 with a longer longitudinal axis, the numbers of the magnetic substances 26 coupled with the LC molecule 24 are correspondingly increased, and vice versa. That is, the numbers of the magnetic substances 26 coupled with the LC molecule 24 is depended on the practical circumstances regarding the size or the form of the adopted LC molecule 24. Even each LC molecule 24 is only couple with one stripe-shaped magnetic substance 26 whose length is approximate or same to that of LC molecule 24. The magnetic substance 26 has a nano-scaling size could be adopted in the present invention to form the combination 25, but the present invention is not limited to be implemented with a nano-scaling magnetic substance 26. In one embodied implementation, the magnetic substances 26 and the LC molecule 24 are coupled with each other as follows. The magnetic substance 26 and the LC molecule 24 have a longitudinal axis respectively and the longitudinal axis of the magnetic substance 26 is first aligned to be parallel to the longitudinal axis of the LC molecule 24. Subsequently, at least one LC molecule 24 is accessed to at least one magnetic substance 26 and both are inherently coupled with each other by an electrostatic force or a van der Waals force, whereby the combination 25 is thus formed.

Please again refer to FIG. 2(a). Since the switch 27 is turned off, the external applied electrical field is not applied to the combination 25 so that the LC molecule 24 in the combination 25 is not influenced by the external applied electrical field. The combination 25 is horizontally rested between the first substrate 20a and the second substrate 20b. That is, the longitudinal axes of the LC molecule 24 and the magnetic substances 26 are approximately parallel to the first substrate 20a and the second substrate 20b. At the time, the plurality of the magnetic substances 26 disposed around the LC molecule 24 are correspondingly arranged in horizontal whereby a horizontal magnetic field Hh is thus formed around the memory cell 200. Such horizontal magnetic field Hh around the memory cell 200 is inducted by the magnetic sensor 28.

Please again refer to FIG. 2(b). Since the switch 27 is turned on, an external applied electrical field is formed between the first electrode 22a and the second electrode 22b and is applied to the combination 25 so that the LC molecule 24 in the combination 25 is influenced by the external applied electrical field. The LC molecule 24 is become to be vertically arranged between the first substrate 20a and the second substrate 20b and the combination 25 is correspondingly arranged in vertical as well. That is the longitudinal axes of the LC molecule 24 and the magnetic substances 26 are approximately perpendicular to the first substrate 20a and the second substrate 20b. At the time, the plurality of the magnetic substances 26 disposed around the LC molecule 24 are correspondingly arranged in vertical whereby a vertical magnetic field Hv is thus formed around the memory cell 200. Such vertical magnetic field Hv around the memory cell 200 is inducted by the magnetic sensor 28.

It is defined that a binary digit 0 is represented by the vertical magnetic field Hv and a binary digit 1 is represented by the horizontal magnetic field Hh, and vice versa. Once the voltage level between the first electrode 20a and the second electrode 20b is varied, the electrical field therebetween is correspondingly varied, whereby the status of the magnetic field around the memory cell 200 would be correspondingly varied or switched between Hv and Hh, such that the memory cell 200 is to be possessed of capability to memorize/storage the binary digital data, but is not only limited to the binary digital data. In this case, two bits digital could be stored in the memory cell 200.

It is noted that the present invention does not only provide two different kinds of the status of the magnetic fields Hv and Hh, but provide more different kinds of the status of the magnetic fields. Typically, it is known that the rotating angle for the LC molecule 24 is proportionally with respect to the strength of the external applied electrical field. For instance, a first further external electric field is designed to be applied to the combination 25 to render the combination 25 rotated with 45° degree against its original position and a 45-degree electric field H45 is thus generated to represent a first given kind of digital data. Alternatively, a second further external electric field is designed to applied to the combination 25 to render the combination 25 rotated with 60° degree against its original position and a 60-degree electric field H60 is thus generated to represent a second given kind of digital data. As long as the magnetic sensor 28 for inducting the magnetic field around the memory cell 200 is sensitive and fast enough to detect any slight variation of the status of the magnetic field, more than two different kinds of the status of the magnetic fields Hv and Hh for representing the digital data could be provided by the present invention for storing digital data. Based on the aforementioned, only one memory cell 200 according to the present application could storage quite a few kinds of the electronic digital data. For instance, a memory cell used for storing one byte digital data, namely storing 8, 16, 32 or more multiple bits digital data could be then provided.

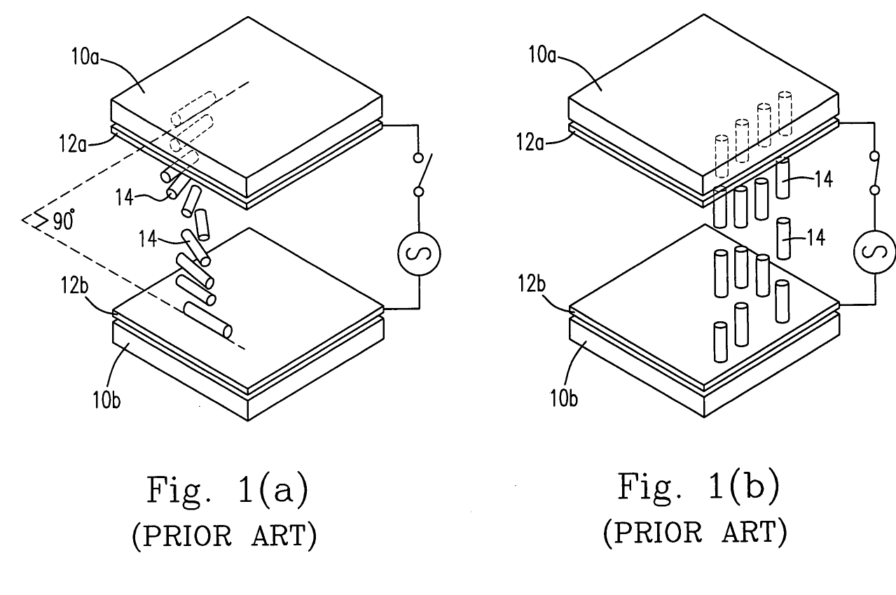

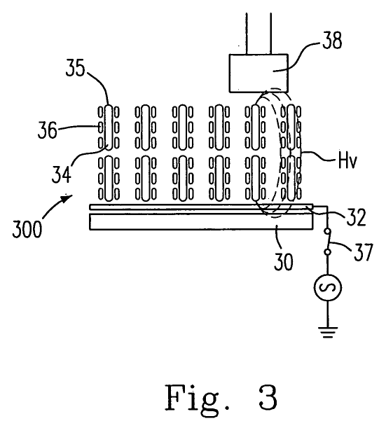

Please keep referring to FIG. 3, which is a schematic diagram illustrating a first alternative embodied architecture for the memory cell according to the present application. The memory cell 300 in FIG. 3 includes a substrate 30, an electrode 32, a LC molecule 34, a magnetic substance 36, a combination 35, a switch 37, a vertical electrical field Hv and a magnetic sensor 38. In this embodied architecture for the memory cell 300, the magnetic sensor 38 is directly exposed to the combination 35 without any isolation by a conventional substrate or other materials as the embodied architecture demonstrated in FIG. 1.

Furthermore, one electrode 32 is intended to be disposed in the embodied architecture in FIG. 3, rather than a couple of electrodes are disposed as a conventional manner. Typically, a voltage is inputted to the electrode 32 as an impulse and the electrical field for driving the LC molecule 34 is correspondingly generated. The LC molecule 34 is stimulated by the impulse-like electrical field, such that the orientational arrangement of the combination 35 is immediately rotated with a certain angle. A certain magnetic field corresponding to such certain angle against the original magnetic field Hh around the memory cell is therefore generated. According to the aforementioned, the certain magnetic field could be either a vertical magnetic field Hv or other magnetic field with respect to the certain angle. Hence, in this setup, two different kinds of the magnetic fields are fully provided for storing the basic 0 and 1 binary digits.

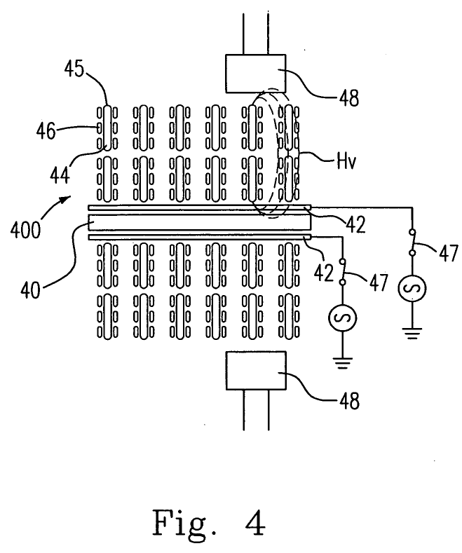

Please refer to FIG. 4, which is a schematic diagram illustrating a second alternative embodied architecture for the memory cell according to the present application. The memory cell 400 in FIG. 4 includes a substrate 40, a first electrode 42a, a second electrode 42b, a LC molecule 44, a magnetic substance 46, a combination 45, a switch 47, a vertical electrical field Hv and a magnetic sensor 38. In this embodied architecture for the memory cell 400, there two electrodes, the first electrode 42a and the second electrode 42b, are respectively disposed on two sides of the substrate 40, which is an ingenious architecture. Two memory cells are simply divided and formed by one substrate 40 sandwiched therebetween and the entire size for two memory cells could be duly shrunk by such architecture. The work principle for the architecture in FIG. 4 is totally same with the aforementioned.

Whether the essence of the memory cell is volatile or non-volatile is determined by the characteristic of the LC molecule 44 adopted in the above-mentioned memory cells 200, 300 and 400 respectively demonstrated in FIGS. 2(a), 2(b), 3 and 4. While a LC molecule 44 with a cholesterol essence is adopted in the memory cells, since such cholesterol LC molecule could contain its orientational arrangement during the period the external applied electrical field is applied to, even if the external applied electrical field is ceased, the memory cells 200, 300 and 400 adopted the cholesterol LC molecule would become an non-volatile memory cell. In contrary, if a nematic LC molecule or a smectic LC molecule is adopted, the memory cells 200, 300 and 400 would be a volatile memory cell, since a nematic LC molecule or a smectic LC molecule are unable to bear the orientational arrangement when the external applied electrical field is applied to.

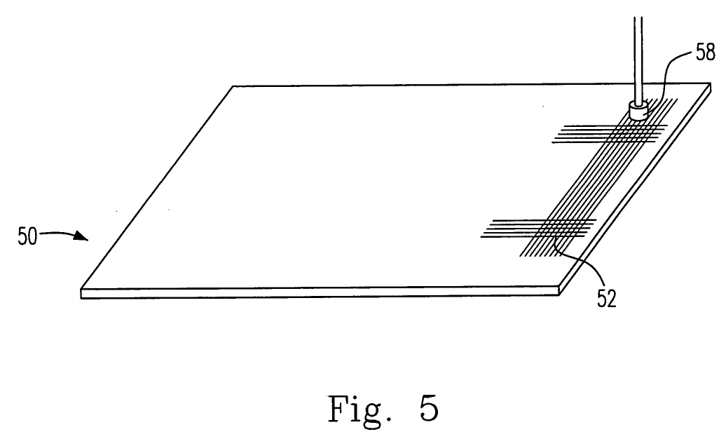

Please keep referring to FIG. 5, which is a schematic diagram illustrating a digital data memory device according to the present application. The memory device 50 as shown in FIG. 5 includes a plurality of the memory cells 52, a switch (not shown in the FIG. 5) and a magnetic sensor 58. The plurality of the memory cells 52 are the memory cells having the above-mentioned technical features. Each memory cells 52 that could be a transistor element are disposed with a switch to turn on or off the voltage for driving the external applied electrical field applied to the plurality of the memory cells 52. Then the magnetic sensor 58 is applied to induct the status of the magnetic field. A digital data memory device 50 is then made up. A digital data is written in the digital data memory device 50 by controlling the status of the magnetic field and is read out from the digital data memory device 50 by inducting the status of the magnetic field by the magnetic sensor 58. A massive digital data is able to be stored in the memory cells 52 by duly increasing the numbers of the memory cells 52. The appearance of the digital data memory device 50 according to the present application is not limited to only a rectangular shape as shown in FIG. 5. For instance, a popular circular shape is able to be applied to the present application as the digital data memory device 50.

While the invention has been described in terms of what are presently considered to be the most practical and preferred embodiments, it is to be understood that the invention need not to be limited to the disclosed embodiment. On the contrary, it is intended to cover various modifications and similar orientational arrangement included within the spirit and scope of the appended claims that are to be accorded with the broadest interpretation, so as to encompass all such modifications and similar structures. According, the invention is not limited by the disclosure, but instead its scope is to be determined entirely by reference to the following claims.

What is claimed is:

1. A memory cell, comprising:
a first electrode receiving a first voltage to form an electric field therearound; and
a combination arranged on the first electrode, comprising a liquid crystal molecule coupled with a magnetic substance for forming a magnetic field therearound,
wherein the magnetic field changing with the first electric field.

2. The memory cell according to claim 1 further comprising a second electrode wherein the combination is arranged between the first electrode and the second electrode and a voltage difference is applied between the first electrode and the second electrode to form an electric field.

3. The memory cell according to claim 2 further comprising a first substrate and a second substrate, on which the first electrode and the second electrode are respectively disposed.

4. The memory cell according to claim 3, wherein the substrate is one of a glass substrate and a semiconductor substrate.

5. The memory cell according to claim 1 further comprising:
a substrate on which the first electrode is disposed.

6. The memory cell according to claim 1 further comprising:
a substrate having a first side, on which the first electrode is disposed, and a second side; and
a second electrode disposed on the second side,
wherein the combination is arranged between the first electrode and the second electrode and the second electrode receives a second voltage to form a second electric field therearound.

7. The memory cell according to claim 1 further comprising a switch for controlling the voltage.

8. The memory cell according to claim 7, wherein the switch is a transistor.

9. The memory cell according to claim 1, wherein the liquid crystal molecule is one selected from a group consisting of a nematic liquid crystal molecule, a smectic liquid crystal molecule, a cholesteric liquid crystal molecule, a discotic liquid crystal molecule, a thermotropic liquid crystal molecule and a recentrant liquid crystal molecule.

10. The memory cell according to claim 1, wherein the magnetic substance has a shape selected from a group consisting of an elongated shape, a pin shape and a stripe shape.

11. The memory cell according to claim 1, wherein the magnetic substance has a longitudinal axis parallel to a longitudinal axis of the liquid crystal molecule.

12. The memory cell according to claim 1, wherein the substance has a nanoscaled size.

13. The memory cell according to claim 1, wherein the liquid crystal molecule and the magnetic substance are coupled with each other by one of an electrostatic force and a van der Waals force for forming the combination.

14. A memory cell, comprising:
an electrode;
a combination arranged on the electrode, comprising a liquid crystal molecule and a magnetic substance,
wherein the arrangement of the combination changes with the an electric field formed by a voltage applied to the electrode.

15. A memory device has a plurality of memory cells as claimed in claim 14.

16. A memory device, comprising:
a plurality of memory cells, each of which comprises:
an electrode; and
a plurality of combinations arranged on the electrode, each of which comprises a liquid crystal molecule and a magnetic substance; and
a magnetic sensor,
wherein a voltage is applied to the electrode to vary an arrangement of the combination so that a variation of a magnetic field formed around the cell is sensed by the magnetic sensor.

17. The memory device according to claim 16 further comprising:
a second electrode,
wherein the combinations are arranged between the first electrode and the second electrode, and a voltage is applied between the first electrode and the second electrode to form an electric field.

18. The memory device according to claim 16, further comprising:
a substrate having a first side, on which the first electrode is disposed, and a second side; and
a second electrode disposed on the second side, where the combinations are arranged between the first electrode and the second electrode,
wherein a first voltage is applied to the first electrode to form a first electric field therearound, and a second voltage is applied to the second electrode to form a second electric field therearound.

19. A data memorizing method, comprising steps of:
applying a voltage to an electrode on which a combination comprising a liquid crystal molecule and a magnetic substance; and
varying the voltage to vary a magnetic field formed around the combination.

20. A device for implementing the method as claimed in claim 19.
